(19) United States
(12) Patent Application Publication
(10) Pub. No.: US 2026/0006723 A1
(43) Pub. Date: Jan. 1, 2026

(54) CIRCUIT BOARD AND ELECTRONIC DEVICE

(71) Applicant: Wuhan Tianma Microelectronics Co., Ltd., Wuhan (CN)

(72) Inventors: Lu GENG, Wuhan (CN); Zhihua YU, Wuhan (CN); Ning XU, Wuhan (CN)

(21) Appl. No.: 19/319,785

(22) Filed: Sep. 5, 2025

(30) Foreign Application Priority Data
May 13, 2025 (CN) 202510615092.2

(51) Int. Cl. H05K 1/18

(52) U.S. Cl. CPC H05K 1/181; H05K 2201/09227; H05K 2201/10318; H05K 2201/10325

(57) ABSTRACT

Provided are a circuit board and an electronic device. The circuit board includes: a first surface and a second surface arranged opposite to each other, where a first connecting seat is arranged on the first surface and includes at least one first positioning pin; a first area, a projection of the first area onto the first surface along a direction perpendicular to a plane of the circuit board covers the first positioning pin; a first-type signal line, where a signal on the first-type signal line is different from a signal on the first positioning pin, and the first-type signal line does not overlap with the first area along the direction; and/or a second-type signal line, where a signal on the second-type signal line is the same as the signal on the first positioning pin, and the second-type signal line overlaps with the first area along the direction.

### CROSS-REFERENCE TO RELATED APPLICATION

The present application claims priority to Chinese Patent Application No. 202510615092.2, filed on May 13, 2025, the content of which is incorporated herein by reference in its entirety.

### TECHNICAL FIELD

The present disclosure relates to the field of circuit board technologies, and in particular, to a circuit board and an electronic device.

### BACKGROUND

In electronic devices, connectors are usually used as tools for interconnection between circuit boards, such as board-to-board connectors. A connector typically includes a male seat and a female seat, which are buckled for use to achieve interconnection of circuit boards.

However, in the prior art, the problem that a positioning pin of the connector is short-circuited with other signal traces is prone to occur. Therefore, a solution is urgently needed.

### SUMMARY

In view of the above, embodiments of the present disclosure provide a circuit board and an electronic device, to resolve the foregoing problem.

In a first aspect, an embodiment of the present disclosure provides a circuit board, including a first surface and a second surface arranged opposite to each other, where a first connecting seat is arranged on the first surface and includes at least one first positioning pin; the circuit board further includes a first area, and a projection of the first area onto the first surface along a direction perpendicular to a plane of the circuit board covers the first positioning pin; the circuit board further includes a first-type signal line, where a signal on the first-type signal line is different from a signal on the first positioning pin, and the first-type signal line does not overlap with the first area along the direction perpendicular to the plane of the circuit board; and/or the circuit board further includes a second-type signal line, where a signal on the second-type signal line is the same as the signal on the first positioning pin, and the second- type signal line overlaps with the first area along the direction perpendicular to the plane of the circuit board.

In a second aspect, based on the same inventive concept, an embodiment of the present disclosure provides an electronic device, including the circuit board as provided in the first aspect.

In the embodiments of the present disclosure, if the first-type signal line is arranged to have no overlap with the first area, then the first-type signal line whose signal is different from the signal of the first positioning pin can avoid the first area where the first positioning pin is located, and the first positioning pin can be kept farther away from the first- type signal line. Even if the first positioning pin is inclined or punctures through the circuit board, the first positioning pin will not come into contact with the first-type signal line, thereby be conducive to avoiding a short circuit between the first positioning pin and the first- type signal line of different attribute.

If the second-type signal line is arranged to overlap the first area, then the second- type signal line whose signal is the same as the signal of the first positioning pin can be arranged near the first positioning pin, so that the second-type signal line is kept closer to the first positioning pin. When the first positioning pin is inclined or punctures through the circuit board, the first positioning pin can come into contact with the second-type signal line of the same attribute, thereby being conducive to avoiding a short circuit between the first positioning pin and the signal line of different attribute.

### BRIEF DESCRIPTION OF DRAWINGS

In order to more clearly illustrate technical solutions of embodiments of the present disclosure, the drawings required to be used in the embodiments will be briefly introduced below. Apparently, the drawings described below are merely some embodiments of the present disclosure. For those of skill in the art, other drawings can be obtained based on these drawings without creative effort.

FIG. 1 is a structural schematic diagram of a circuit board according to an embodiment of the present disclosure;

FIG. 2 is a structural schematic diagram of another circuit board according to an embodiment of the present disclosure;

FIG. 3 is a schematic diagram of a first surface of a circuit board according to an embodiment of the present disclosure;

FIG. 4 is a schematic diagram of a first connecting seat and a second connecting seat according to an embodiment of the present disclosure;

FIG. 5 is a schematic diagram of a first surface of another circuit board according to an embodiment of the present disclosure;

FIG. 6 is a schematic diagram of a first surface of another circuit board according to an embodiment of the present disclosure;

FIG. 7 is a schematic diagram of a second surface of a circuit board according to an embodiment of the present disclosure;

FIG. 8 is a schematic diagram of a layout of a circuit board according to an embodiment of the present disclosure;

FIG. 9 is a schematic diagram of a second surface of another circuit board according to an embodiment of the present disclosure;

FIG. 10 is a schematic diagram of a layout of another circuit board according to an embodiment of the present disclosure; and

FIG. 11 is a schematic diagram of an electronic device according to an embodiment of the present disclosure.

### DESCRIPTION OF EMBODIMENTS

In order to better understand technical solutions of the present disclosure, embodiments of the present disclosure are described in detail below in conjunction with the drawings.

It should be clear that the described embodiments are merely a part of the embodiments of the present disclosure rather than all of the embodiments. All other embodiments obtained by those of skill in the art without creative efforts based on the embodiments of the present disclosure shall fall within the scope of protection of the present disclosure.

The terms used in the embodiments of the present disclosure are only for the purpose of describing specific embodiments and are not intended to limit the present disclosure. The singular forms "a/an", "said" and "the" used in the embodiments of the present disclosure and the appended claims are also intended to include the plural forms, unless the context clearly indicates otherwise.

It should be understood that the term "and/or" used herein is only a description of the correlation relationship between associated objects, indicating that there can be three relationships. For example, A and/or B can mean: A exists alone, A and B exist simultaneously, and B exists alone. In addition, the character "/" herein generally indicates that the associated objects before and after the character are in an "or" relationship.

It is apparent to those of skill in the art that various modifications and changes can be made in the present disclosure without departing from the scope of the present disclosure. Therefore, the present disclosure is intended to cover the modifications and changes of the present disclosure that fall within the scope of the corresponding claims (claimed technical solutions) and their equivalents. It should be noted that the implementations provided by the embodiments of the present disclosure can be combined with each other if there is no contradiction.

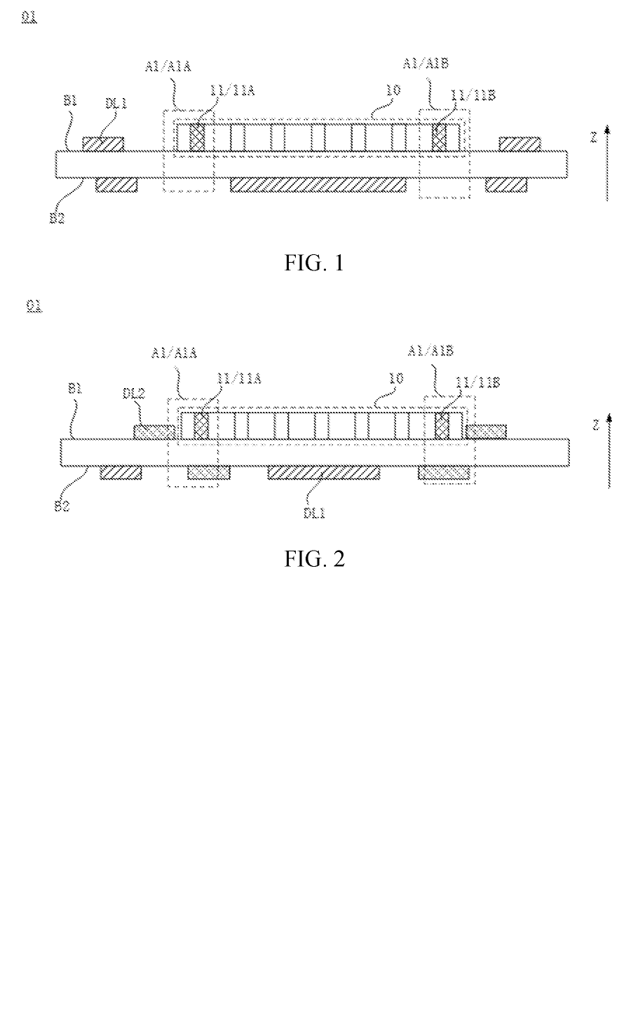

FIG. 1 is a structural schematic diagram of a circuit board according to an embodiment of the present disclosure, and FIG. 2 is a structural schematic diagram of another circuit board according to an embodiment of the present disclosure.

Embodiments of the present disclosure provide a circuit board 01, as shown in FIGS. 1 and 2, the circuit board 01 includes a first surface B1 and a second surface B2 arranged opposite to each other, the first surface B 1 and the second surface B2 can be arranged opposite to each other in a direction Z perpendicular to a plane of the circuit board 01, the first surface B 1 may be a front face of the circuit board 01, and the second surface B2 can be a back face of the circuit board 01.

A first connecting seat 10 is arranged on the first surface B1, and the first connecting seat 10 includes at least one first positioning pin 11. The first positioning pin 11 is configured to determine the position of the first connecting seat 10 on the first surface B1.

Optionally, the first positioning pin 11 is further configured to transmit a ground signal.

Optionally, the first connecting seat 10 is a male seat or a female seat in a connector. The connector may be a board-to-board connector.

The circuit board 01 includes a first area A1, and a projection of the first area Al onto the first surface B1 along the direction Z perpendicular to the plane of the circuit board 01 covers the first positioning pin 11.

The circuit board 01 further includes a first-type signal line DL1, a signal on the first-type signal line DL1 is different from a signal on the first positioning pin 11, and the first-type signal line DL1 does not overlap with the first area Al along the direction Z perpendicular to the plane of the circuit board 01; and/or, the circuit board 01 further includes a second-type signal line DL2, a signal on the second-type signal line DL2 is the same as the signal on the first positioning pin 11, and the second-type signal line DL2 overlaps with the first area Al along the direction Z perpendicular to the plane of the circuit board 01.

That is to say, as shown in FIG. 1, the first-type signal line DL1 is not arranged in the first area A1, so that the first-type signal line DL1 whose signal is different from the signal of the first positioning pin 11 can avoid the first area Al where the first positioning pin 11 is located. Alternatively, as shown in FIG. 2, the second-type signal line DL2 is arranged in the first area A1, so that the second-type signal line DL2 whose signal is the same as the signal of the first positioning pin 11 is closer to the first positioning pin 11.

Of course, as shown in FIG. 2, only the second-type signal line DL2 but not the first-type signal line DL1 may be arranged in the first area A1.

The inventors of the present disclosure have found through research that a board- to-board connector generally includes a male seat and a female seat, and the interconnection between circuit boards is realized by mutually buckling the male seat and the female seat. However, in the prior art, a signal trace of different attribute is generally arranged beneath or around a positioning pin of the connector. During buckling the connector for use, a situation is likely to occur where the positioning pin is inclined or pressed through the circuit board to be short-circuited with the signal trace of different attribute.

Therefore, in the embodiments of the present disclosure, the first-type signal line DL1 is arranged to have no overlap with the first area A1, and/or the second-type signal line DL2 is arranged to overlap with the first area A1, so as to avoid a short circuit between the first positioning pin 11 and the signal line of different attribute.

If the first-type signal line DL1 is arranged to have no overlap with the first area A1, then the first-type signal line DL1 whose signal is different from the signal of the first positioning pin 11 can avoid the first area Al where the first positioning pin 11 is located, and the first positioning pin 11 can be kept farther away from the first-type signal line DL1. Even if the first positioning pin 11 is inclined or punctures through the circuit board 01, the first positioning pin 11 will not come into contact with the first-type signal line DL1, thereby be conducive to avoiding a short circuit between the first positioning pin 11 and the first-type signal line DL1 of different attribute.

If the second-type signal line DL2 is arranged to overlap the first area A1, then the second-type signal line DL2 whose signal is the same as the signal of the first positioning pin 11 can be arranged near the first positioning pin 11, so that the second-type signal line DL2 is kept closer to the first positioning pin 11. When the first positioning pin 11 is inclined or punctures through the circuit board 01, the first positioning pin 11 tends to come into contact with the second-type signal line DL2 of the same attribute, thereby being conducive to avoiding a short circuit between the first positioning pin 11 and the signal line of different attribute.

It should be noted that in an embodiment of the present disclosure, the first connecting seat 10 can include a plurality of first positioning pins 11, and the circuit board 01 can include a plurality of first areas Al arranged corresponding to the first positioning pins 11.

For example, as shown in FIGS. 1 and 2, the first connecting seat 10 includes two first positioning pins 11, which are respectively a first positioning pin 11A and a first positioning pin 11B. The first positioning pin 11A and the first positioning pin 11B are located at two ends of the first connecting seat 10 and are configured to determine the specific position of the first connecting seat 10 on the circuit board 01.

In this case, the circuit board 01 can include two first areas A1, which can be respectively a first area AlA and a first area AlB. Along the direction Z perpendicular to the plane of the circuit board 01, the first area AlA covers the first positioning pin 11A, and the first area AlB covers the first positioning pin 11B.

Further, along the direction Z perpendicular to the plane of the circuit board 01, the first area AlA does not overlap with the first positioning pin 11B, and the first area AlB does not overlap with the first positioning pin 11A.

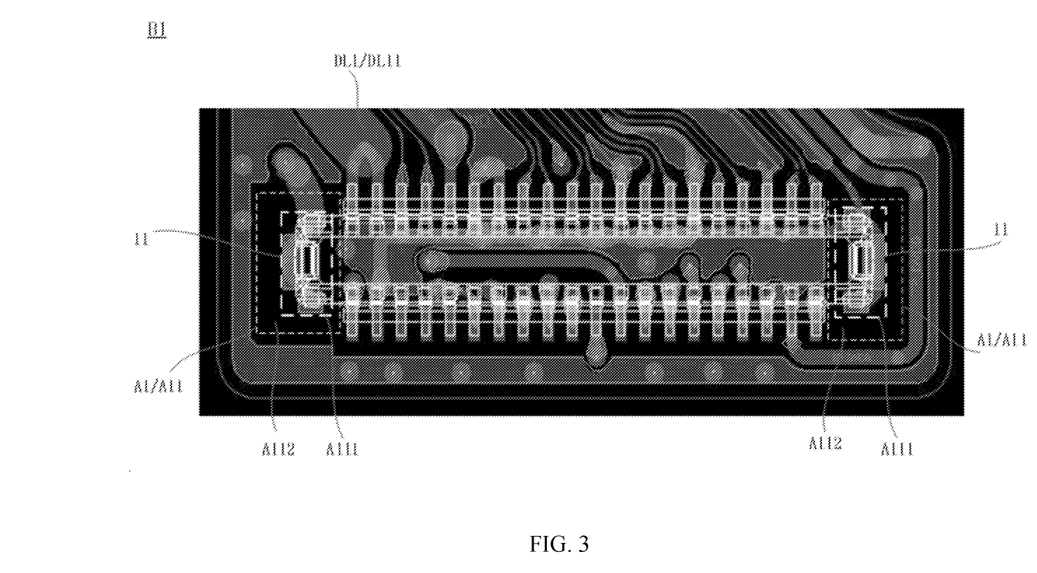

FIG. 3 is a schematic diagram of a first surface of a circuit board according to an embodiment of the present disclosure.

In an implementation of the present disclosure, as shown in FIG. 3, the first area Al includes a first sub-area All located on the first surface B1, and the first sub-area All covers the first positioning pin 11 along the direction perpendicular to the plane of the circuit board 01.

The first-type signal line DL1 includes a first signal line DL11 located on the first surface B1, and the first signal line DL11 does not pass through the first sub-area All. Of course, a signal on the first signal line DL11 is different from the signal on the first positioning pin 11.

In the implementation of the present disclosure, by making the first signal line DL11 not pass through the first sub-area All on the first surface B1, a space-avoiding design for the signal line of different attribute can be implemented on a surrounding area of the first positioning pin 11, which is conducive to keeping the first signal line DL11 on the first surface B1 farther away from the first positioning pin 11. Even if the first positioning pin 11 is inclined and punctures through an insulation protective material on the first surface B 1, it will not come into contact with the first signal line DL11, thereby being conducive to avoiding a short circuit between the first positioning pin 11 and the first signal line DL11 of different attribute, and further being conducive to improving the service life of the circuit board 01.

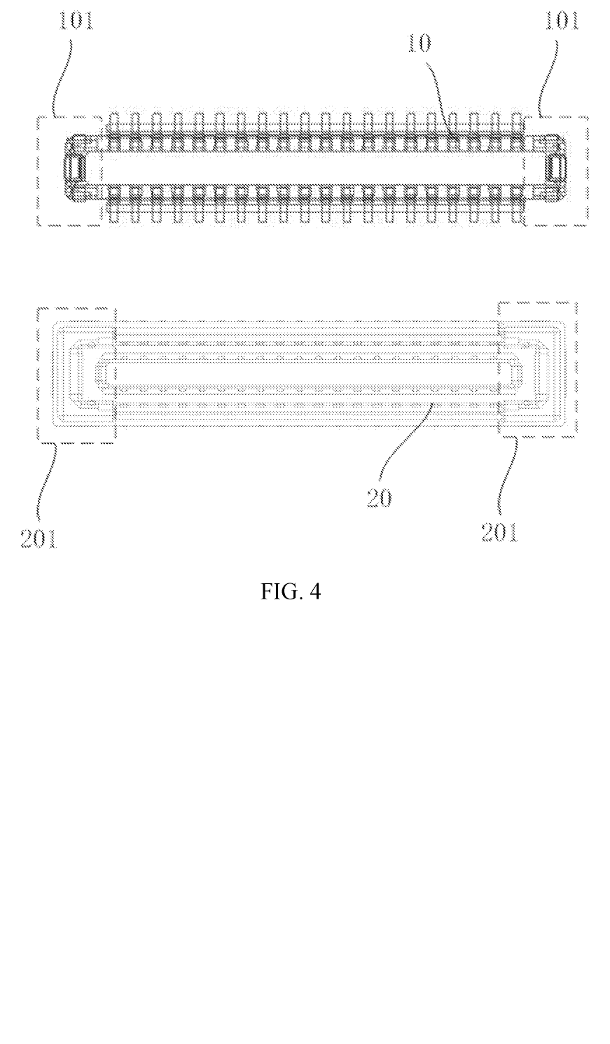

FIG. 4 is a schematic diagram of a first connecting seat and a second connecting seat according to an embodiment of the present disclosure.

In an implementation of the present disclosure, the first connecting seat 10 is configured for corresponding electrical connection with a second connecting seat 20. For example, as shown in FIG. 4, the first connecting seat 10 may be a male seat, the second connecting seat 20 may be a female seat, and the first connecting seat 10 and the second connecting seat 20 can realize corresponding electrical connection with each other through plug-in interconnection.

The first connecting seat 10 includes a first positioning portion 101, and the first positioning pin 11 (not shown in the figure) is located on the first positioning portion 101. The second connecting seat 20 includes a second positioning portion 201 arranged corresponding to the first positioning portion 101. That is, after the first connecting seat 10 and the second connecting seat 20 are plugged-in and interconnected, along an arrangement direction of the first connecting seat 10 and the second connecting seat 20, the first positioning portion 101 and the second positioning portion 201 overlap with each other.

It can be understood that a second positioning pin (not shown in the figure) for corresponding connection with the first positioning pin 11 may be arranged in the second positioning portion 201. After the first connecting seat 10 and the second connecting seat 20 are plugged-in and interconnected, the first positioning pin is connected with the second positioning pin.

As can be seen from the foregoing analysis, the first connecting seat 10 can include a plurality of first positioning pins 11, and therefore, the first connecting seat 10 can include a plurality of first positioning portions 101, and different first positioning pins 11 may be arranged on different first positioning portions 101. In this case, the second connecting seat 20 can include a plurality of second positioning portions 201, and the second positioning portions 201 may be in one-to-one correspondence with the first positioning portions 101.

For example, as shown in FIG. 4, the first connecting seat 10 includes two first positioning portions 101, and the second connecting seat 20 includes two second positioning portions 201.

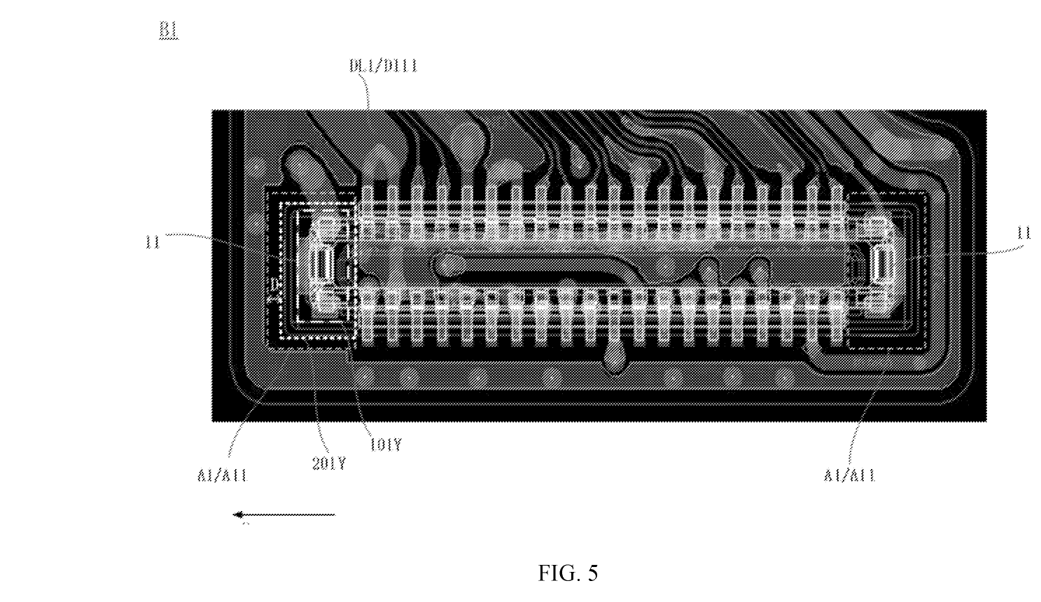

As shown in FIG. 5, which is a schematic diagram of a first surface of another circuit board according to an embodiment of the present disclosure, along the direction perpendicular to the plane of the circuit board 01, a projection of the first positioning portion 101 onto the first surface B1 is a first projection 10lY, and a projection of the second positioning portion 201 onto the first surface B1 is a second projection 201Y; and

the first sub-area All protrudes beyond a larger one in area of the first projection lOlY and the second projection 201Y along a first direction X, and the first direction is parallel to the plane of the circuit board.

Since the first sub-area A11 covers the first positioning pin 11, on the first surface B1, while the first sub-area All overlaps with the first projection 101Y and the second projection 201Y, there is still at least a partial area of the first sub-area All that does not overlap with either the first projection 101Y or the second projection 201Y.

For example, as shown in FIG. 5, an area of the second projection 201Y is greater than an area of the first projection 101Y, and the first sub-area A11 protrudes beyond the second projection 201Y along the first direction X. The first direction X may be a direction from the first positioning pin 11 to an edge of the circuit board 01.

In the embodiment of the present disclosure, since the first signal line DL11 does not pass through the first sub-area A11, the first sub-area A11 is arranged to protrude beyond the larger one in area of the first projection 101Y and the second projection 201Y along the first direction X. In this case, along the first direction X, the first signal line DL11 can be farther away from the first positioning pin 11, and even if the first positioning pin 11 is inclined or the second positioning pin in the second connecting seat 20 that corresponds to the first positioning pin 11 is inclined, it will not be short-circuited with the first signal line DL11 of different attribute, which is conducive to improving the service life of the circuit board 01.

Optionally, as shown in FIG. 5, a distance by which the first sub-area All protrudes beyond the larger one in area of the first projection 101Y and the second projection 201Y along the first direction X is D, where 0.15 mm < D < 0.25 mm.

Based on this arrangement, while avoiding the first positioning pin 11 and/or the second positioning pin from being short-circuited with the first signal line DL11 of different attribute, it is possible to avoid the first sub-area All from expanding outward too much relative to the first projection 101Y and the second projection 201Y along the first direction X, which is conducive to improving the space utilization rate of the circuit board 01.

As shown in conjunction with FIGS. 3 and 4, in an embodiment of the present disclosure, the first sub-area A11 includes a positioning area A111 where the first positioning portion 101 is arranged, and an adjacent area A112 adjacent to the positioning area A111, and the adjacent area A112 at least partially surrounds the positioning area A111.

That is to say, the first sub-area All includes the positioning area A111 and the adjacent area A112 surrounding at least a part of the positioning area A111, and the first positioning portion 101 is arranged in the positioning area A111. The adjacent area A112 may be a surrounding area of the first positioning portion 101.

For example, the adjacent area A112 completely surrounds the positioning area A111.

As can be seen from the foregoing analysis, the first signal line DL11 does not pass through the first sub-area A111, and therefore, the first signal line DL11 does not pass through the adjacent area A112. In the embodiment of the present disclosure, by making the adjacent area A112 surround at least a part of the positioning area A111, the adjacent area A112 can be arranged between the first positioning portion 101 and the first signal line DL11 in multiple directions, which is conducive to keeping the first positioning portion 101 farther away from the first signal line DL11 in the multiple directions, thereby being conducive to avoiding a case where the first positioning pin 11 is inclined to be short-circuited with the first signal line DL11 in the multiple directions, and further being conducive to improving the service life of the circuit board 01.

Optionally, no signal trace is arranged in the adjacent area A112. That is, in the adjacent area A112, neither a trace whose signal is different from the signal of the first positioning pin 11 nor a trace whose signal is the same as the signal of the first positioning pin 11 can be arranged.

Based on this arrangement, while avoiding a short circuit between the first positioning pin 11 and a signal trace, it is conducive to reducing the number of signal traces in the first sub-area All and increasing the distance between signal traces on the opposite sides of the adjacent area A112, which is conducive to lowering the process difficulty.

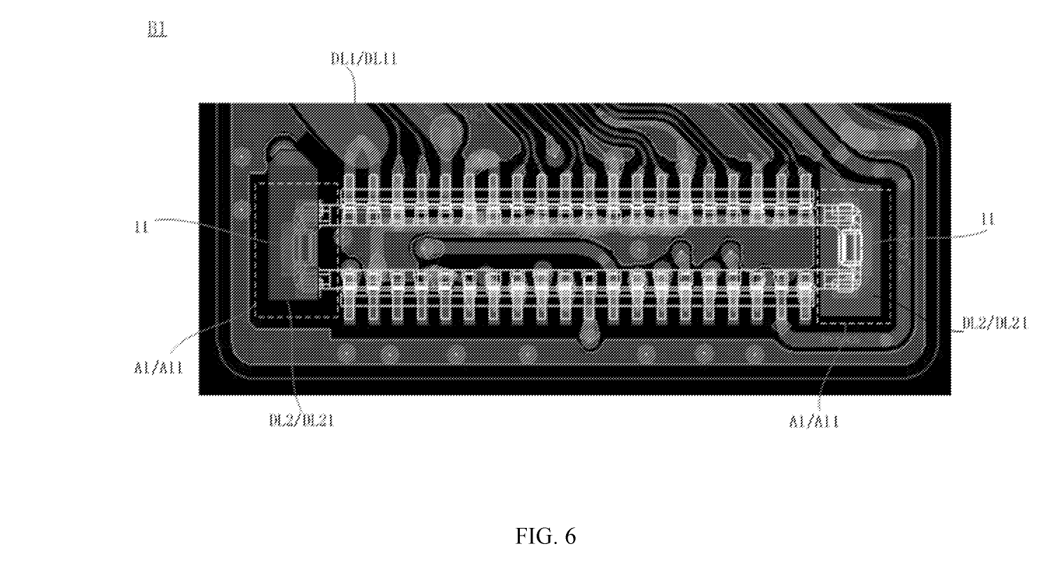

FIG. 6 is a schematic diagram of a first surface of another circuit board according to an embodiment of the present disclosure.

In an embodiment of the present disclosure, as shown in FIG. 6, the first area Al includes a first sub-area All located on the first surface B1, and the first sub-area All covers the first positioning pin 11 along the direction perpendicular to the plane of the circuit board 01.

The second-type signal line DL2 includes a second signal line DL21 located on the first surface B1, and at least a part of the second signal line DL21 is located in the first sub- area A11. That is, on the first surface B1, the second signal line DL21 passes through the first sub-area All. A signal on the second signal line DL21 is the same as the signal on the first positioning pin 11.

In the embodiment of the present disclosure, by arranging at least a part of the second signal line DL21 to be located in the first sub-area All, the second signal line DL21 can be arranged to be closer to the first positioning pin 11 in the first sub-area A11. For example, the second signal line DL21 is adjacent to the first positioning pin 11, with no other signal traces arranged between the two. Or, as shown in FIG. 6, the second signal line DL21 is connected to the first positioning pin 11. In this way, even if the first positioning pin 11 is inclined and punctures through the insulation protective material on the first surface B1, the first positioning pin 11 will only come into contact with the second signal line DL21 of the same attribute, thereby being conducive to avoiding a short circuit between the first positioning pin 11 and a signal trace of different attribute, and further being conducive to improving the service life of the circuit board 01.

Moreover, the second signal line DL21 passing through the first sub-area All is also conducive to improving the space utilization rate of the circuit board 01.

It should be noted that when the circuit board 01 includes a plurality of first positioning pins 11, a plurality of first sub-areas All can be arranged on the first surface B1, and the same technical solution may be adopted in different first sub-areas A11 to avoid short circuits between the first positioning pins 11 and the signal lines of different attribute. For example, as shown in FIG. 5, the solution where the first signal line DLll avoids the first sub- area A11 is adopted in all different first sub-areas A11. For another example, as shown in FIG. 6, the solution where the second signal line DL21 passes through the first sub-area All is adopted in all different first sub-areas A11.

In addition, different first sub-areas A11 may also adopt different technical solutions to avoid the short circuits between the first positioning pins 11 and the signal lines of different attribute. For example, among the plurality of first sub-areas All, the solution where the first signal line DLll avoids the first sub-area All is adopted in a part of the first sub-areas All, and the solution where the second signal line DL21 passes through the first sub-area A11 is adopted in the other part of the first sub-areas A11.

Optionally, in the first sub-area All, an area of the second signal line DL21 is not less than 50% of an area of the first sub-area All. Based on this arrangement, the second signal line DL21 can be made more in area in the first sub-area A11, which is conducive to enhancing the reliability of contact between the first positioning pin 11 and the second signal line DL21 when the first positioning pin 11 is inclined, and avoiding a short circuit between the first positioning pin 11 and the signal trace of different attribute.

Meanwhile, in the first sub-area A11, a line width of the second signal line DL21 may also be made larger, which is conducive to reducing the resistance of the second signal line DL21 and improving the electrical performance of the second signal line DL21.

As shown in FIG. 6, in an implementation of the present disclosure, the second signal line DL21 is electrically connected to the first positioning pin 11, and the second signal line DL21 covers the first positioning pin 11 along the direction perpendicular to the plane of the circuit board 01.

In the implementation, by making the second signal line DL21 electrically connected to the first positioning pin 11 and cover the first positioning pin 11, the first positioning pin 11 can be in contact with the second signal line DL21. Even if the first positioning pin 11 is inclined, it will still easily maintain contact with the second signal line DL21, which is conducive to further avoiding a short circuit between the first positioning pin 11 and another signal trace of different attribute.

Of course, when the second signal line DL21 is made to cover the first positioning pin 11, the line width of the second signal line DL21 can be set larger, so as to reduce the resistance of the second signal line DL21 and improve the electrical performance of the second signal line DL21.

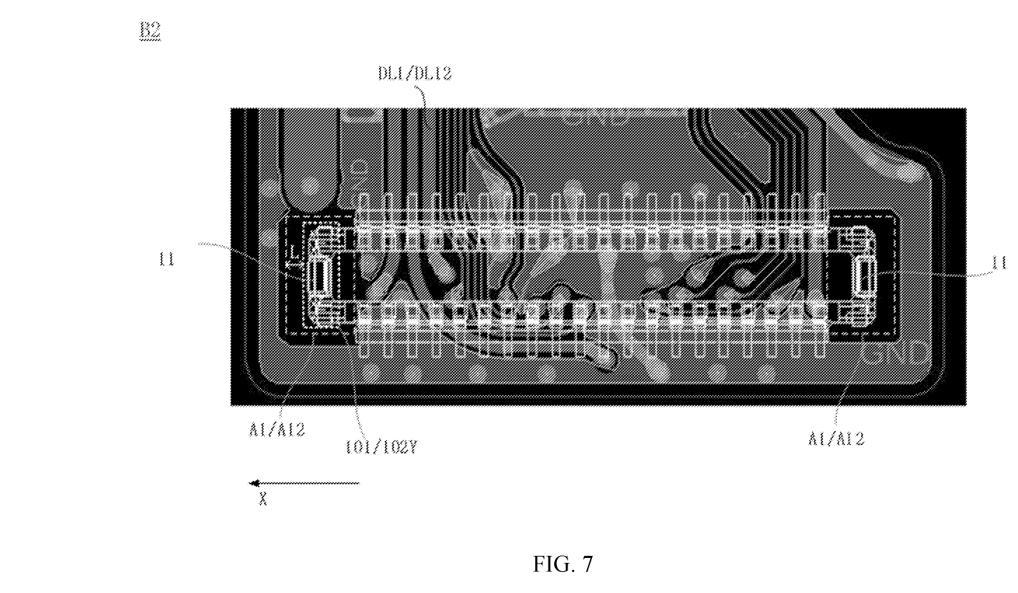

FIG. 7 is a schematic diagram of a second surface of a circuit board according to an embodiment of the present disclosure.

In an embodiment of the present disclosure, as shown in FIG. 7, the first area Al includes a second sub-area A12 located on the second surface B2, and the second sub-area A12 covers the first positioning pin 11 along the direction perpendicular to the plane of the circuit board 01. An area of the second sub-area A12 may be the same as or different from the area of the first sub-area A11.

The first-type signal line DL1 includes a third signal line DL12 located on the second surface B2, a signal on the third signal line DL12 is different from the signal on the first positioning pin 11, and the third signal line DL12 does not pass through the second sub- area A12.

In the embodiment of the present disclosure, by making the third signal line DL12 not pass through the second sub-area A12 on the second surface B2, a space-avoiding design for the signal line of different attribute can be implemented on the opposite side of the first positioning pin 11. Even if the first positioning pin 11 punctures through the circuit board 01 to the second surface B2, it will not come into contact with the third signal line DL12, thereby being conducive to avoiding a short circuit between the first positioning pin 11 and the third signal line DL12 of different attribute, and further being conducive to improving the service life of the circuit board 01.

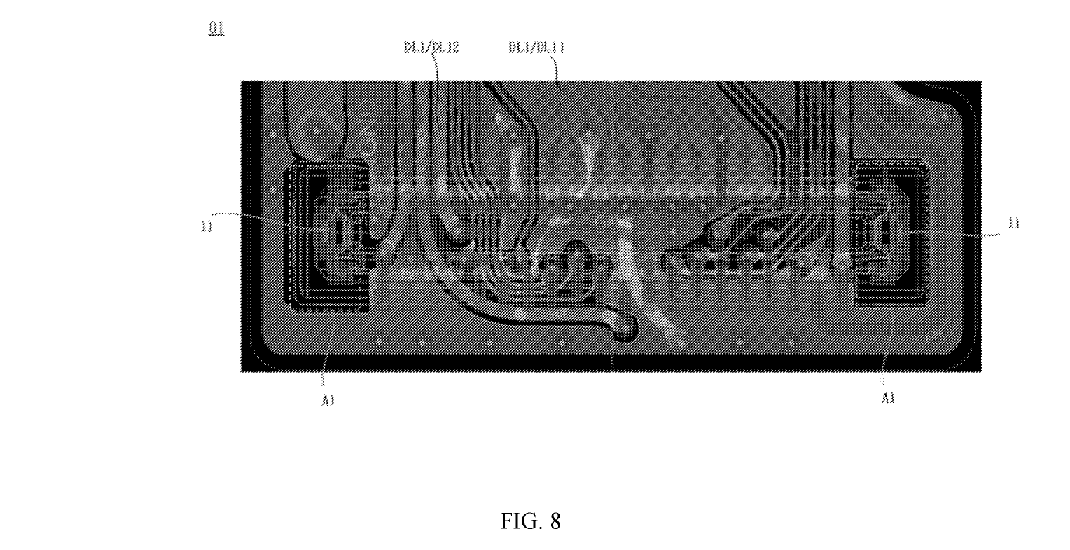

In this case, as shown in FIG. 8, which is a schematic diagram of a layout of a circuit board according to an embodiment of the present disclosure, on the first surface B1, the first signal line DL11 can be made not to pass through the first sub-area All, so that a space-avoiding design for the signal line of different attribute is implemented on the surrounding area of the first positioning pin 11. That is, on both the first surface B1 and the second surface B2, first-type signal lines DL1 are arranged no to pass through the first area A1, implementing a design where the signal lines of different attribute avoid the first area A1.

In addition, the second signal line DL21 may also be made to pass through the first sub-area All, with the signal trace of the same attribute arranged around the first positioning pin 11. That is, on the second surface B2, the signal line of different attribute may be arranged not to pass through the first area A1, implementing an avoiding design for the first area A1. On the first surface B1, the signal line of the same attribute are arranged to pass through the first area A1, implementing a design with the signal line of the same attribute for the first area A1.

In an implementation of the present disclosure, as shown in conjunction with FIGS. 4 and 7, the first connecting seat 10 includes a first positioning portion 101, and the first positioning pin 11 is located on the first positioning portion 101.

Along the direction perpendicular to the plane of the circuit board 01, the second sub-area A12 covers the first positioning portion 101.

In this implementation, by arranging the second sub-area A12 to cover the first positioning portion 101, the second sub-area A12 can be expanded outward relative to the position of the first positioning pin 11. Since the third signal line DL12 does not pass through the second sub-area A12, when the first positioning pin 11 punctures through to the second surface B2, it is conducive to improving the reliability of avoiding a short circuit between the first positioning pin 11 and the third signal line DL12, thereby being conducive to further improving the service life of the circuit board 01.

Optionally, as shown in FIG. 7, a projection of the first positioning portion 101 onto the second surface B2 along the direction perpendicular to the plane of the circuit board 01 is a third projection 102Y.

A distance by which the second sub-area A12 protrudes beyond the third projection 102Y along the first direction X is L, where 0.15 mm < L < 0.25 mm. The first direction X is parallel to the plane of the circuit board.

For example, the first direction X may be a direction from the first positioning pin 11 to an edge of the circuit board 01.

Based on this arrangement, while avoiding a short circuit between the first positioning pin 11 and the third signal line DL12 after the first positioning pin 11 punctures through to the second surface B2, it is possible to avoid the second sub-area A12 from expanding outward too much relative to the position of the first positioning pin 11, which is conducive to improving the space utilization rate of the circuit board 01.

Optionally, no signal trace is arranged in the second sub-area A12. That is, in the second sub-area A12, neither a trace whose signal is different from the signal of the first positioning pin 11 nor a trace whose signal is the same as the signal of the first positioning pin 11 can be arranged.

Based on this arrangement, there is no need to arrange a signal trace in the second sub-area A12. While avoiding a short circuit between the first positioning pin 11 and a signal trace after the first positioning pin 11 punctures through to the second surface B2, it is possible to increase the distance between signal traces on the opposite sides of the second sub-area A12, which is conducive to lowering the process difficulty.

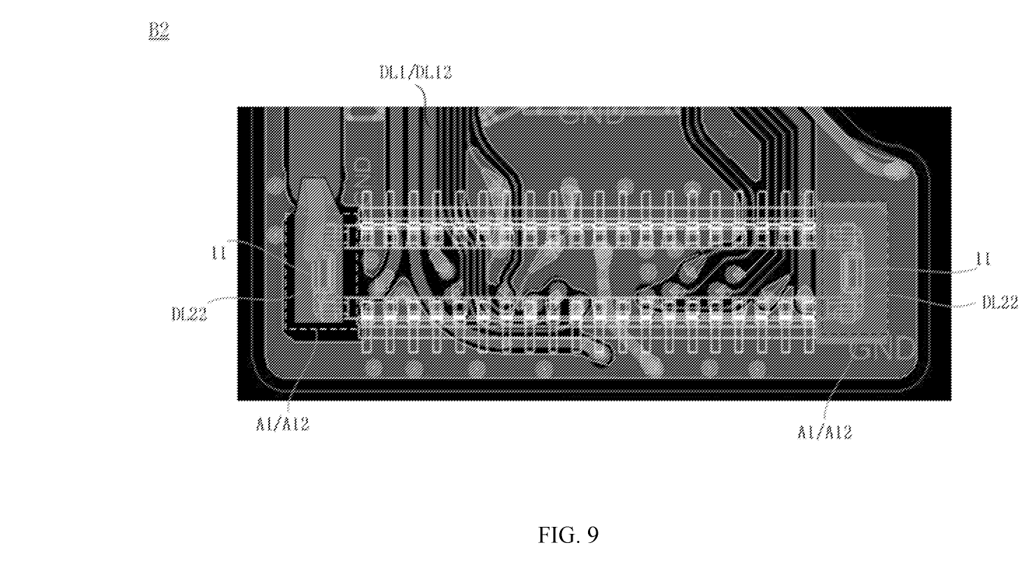

FIG. 9 is a schematic diagram of a second surface of another circuit board according to an embodiment of the present disclosure.

In an embodiment of the present disclosure, as shown in FIG. 9, the first area Al includes a second sub-area A12 located on the second surface B2, and the second sub-area A12 covers the first positioning pin 11 along the direction perpendicular to the plane of the circuit board 01. An area of the second sub-area A12 may be the same as or different from the area of the first sub-area A11.

The second-type signal line DL2 includes a fourth signal line DL22 located on the second surface B2, a signal on the fourth signal line DL22 is the same as the signal on the first positioning pin 11, and at least a part of the fourth signal line DL22 is located in the second sub-area A12. That is, the fourth signal line DL22 can pass through the second sub-area A12.

In the embodiment of the present disclosure, by arranging at least a part of the fourth signal line DL22 in the second sub-area A12, the fourth signal line DL22 can be arranged to be closer to the position of the first positioning pin 11 in the second sub-area A12. When the first positioning pin 11 punctures through to the second surface B2, it is easily for the first positioning pin 11 to come into contact with the fourth signal line DL22 of the same attribute, thereby being conducive to avoiding a short circuit between the first positioning pin 11 and the signal trace of different attribute, and further being conducive to improving the service life of the circuit board 01.

Meanwhile, proposing the fourth signal line DL22 to pass through the second sub- area A12 is also conducive to improving the space utilization rate of the circuit board 01.

It should be noted that when the circuit board 01 includes a plurality of first positioning pins 11, a plurality of second sub-areas A12 can be arranged on the second surface B2, and the same technical solution may be adopted in different second sub-areas A12 to avoid short circuits between the first positioning pins 11 and the signal lines of different attribute. For example, as shown in FIG. 7, the solution where the third signal line DL12 avoids the second sub-area A11 is adopted in all different second sub-areas A12. For another example, as shown in FIG. 9, the solution where the forth signal line DL22 passes through the second sub-area A12 is adopted in all different first sub-areas A11.

In addition, different second sub-areas A12 may also adopt different technical solutions to avoid the short circuits between the first positioning pins 11 and the signal lines of different attribute. For example, among the plurality of second sub-areas A12, the solution where the third signal line DL12 avoids the second sub-area A12 is adopted in a part of the second sub-areas A12, and the solution where the forth signal line DL22 passes through the second sub-area A12 is adopted in the other part of the second sub-areas A12.

Optionally, as shown in FIG. 9, a projection of the fourth signal line DL22 onto the first surface B 1 along the direction perpendicular to the plane of the circuit board 01 covers the first positioning pin 11.

Based on this arrangement, when the first positioning pin 11 punctures through to the second surface B2, it is possible to improve the reliability of contact between the first positioning pin 11 and the fourth signal line DL22, which is conducive to further avoiding short circuits between the first positioning pin 11 and other signal traces of different attributes.

Meanwhile, making the projection of the fourth signal line DL22 onto the first surface B1 cover the first positioning pin 11 is also conducive to make a line width of the fourth signal line DL22 larger, which is conducive to reducing the resistance of the fourth signal line DL22 and improving the electrical performance of the fourth signal line DL22.

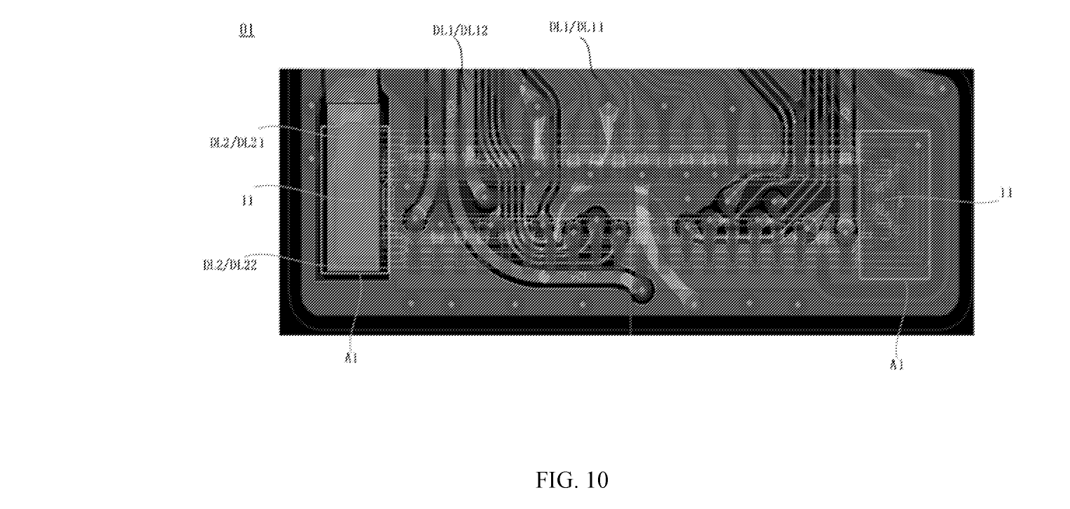

In this case, as shown in FIG. 10, which is a schematic diagram of a layout of another circuit board according to an embodiment of the present disclosure, and on the first surface B1, the second signal line DL21 can be made to pass through the first area All, with the signal trace of the same attribute arranged around the first positioning pin 11. That is, the second-type signal lines DL2 are arranged on both the first surface B1 and the second surface B2 to pass through the first area A1, and the same-attribute signal line design is carried out on the first area A1.

In addition, the first signal line DLl1 may also made to not pass through the first sub-area A11, and a space-avoiding design for the signal line of different attribute can be implemented on a surrounding area of the first positioning pin 11. That is, on the second surface B2, the second-type signal line DL2 may be arranged to pass through the first area A1, implementing a design with the signal line of the same attribute for the first area A1. On the first surface B 1, the signal lines with different attributes may be arranged to not pass through the first area A1, implementing an avoiding design for the first area A1.

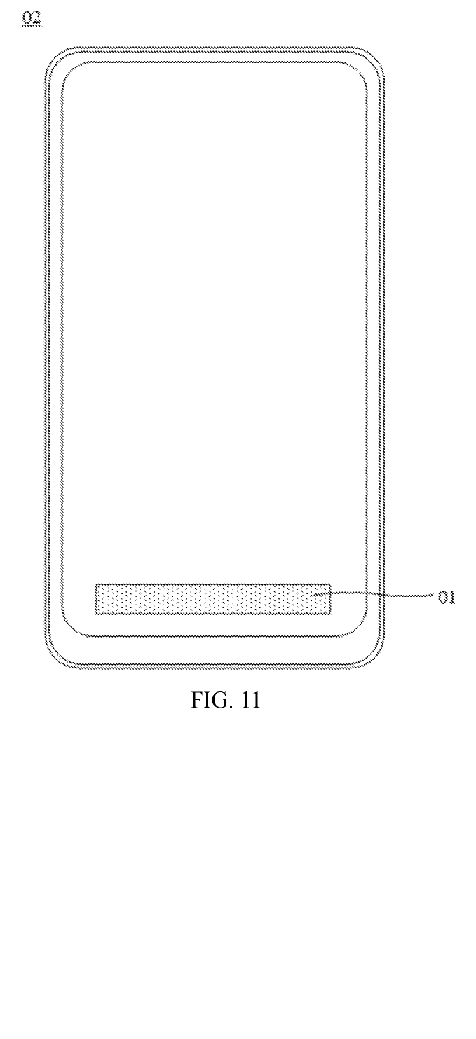

FIG. 11 is a schematic diagram of an electronic device according to an embodiment of the present disclosure.

An embodiment of the present disclosure further provides an electronic device 02, as shown in FIG. 11, the electronic device 02 includes the circuit board 01 provided by any of the foregoing embodiments. The electronic device 02 may be a mobile phone as shown in FIG. 11, or may be a terminal device having a display interface such as a television, a display, a tablet computer, or a vehicle-mounted computer, or may be a smart display wearable device such as a smart watch or a smart bracelet, or may be a communication device such as a server, a memory, a base station, or may be a smart car, etc. The specific form of the above- mentioned electronic device is not particularly limited in the embodiments of the present disclosure.

In the electronic device 02, if the first-type signal line DL1 is arranged to have no overlap with the first area A1, then the first-type signal line DL1 whose signal is different from the signal of the first positioning pin 11 can avoid the first area Al where the first positioning pin 11 is located, and the first positioning pin 11 can be kept farther away from the first-type signal line DL1. Even if the first positioning pin 11 is inclined or punctures through the circuit board 01, the first positioning pin 11 will not come into contact with the first-type signal line DL1, thereby be conducive to avoiding a short circuit between the first positioning pin 11 and the first-type signal line DL1 of different attribute.

If the second-type signal line DL2 is arranged to overlap the first area A1, then the second-type signal line DL2 whose signal is the same as the signal of the first positioning pin 11 can be arranged near the first positioning pin 11, so that the second-type signal line DL2 is kept closer to the first positioning pin 11. When the first positioning pin 11 is inclined or punctures through the circuit board 01, the first positioning pin 11 can come into contact with the second-type signal line DL2 of the same attribute, thereby being conducive to avoiding a short circuit between the first positioning pin 11 and the signal line of different attribute.

The above are merely preferred embodiments of the present disclosure and are not intended to limit the present disclosure. Any modifications, equivalent substitutions, improvements and the like made within the spirit and principle of the present disclosure shall be included within the scope of protection of the present disclosure.

What is claimed is:

1. A circuit board, comprising a first surface and a second surface arranged opposite to each other, wherein a first connecting seat is arranged on the first surface and comprises at least one first positioning pin;
the circuit board further comprises a first area, and a projection of the first area onto the first surface along a direction perpendicular to a plane of the circuit board covers the first positioning pin;
the circuit board further comprises a first-type signal line, wherein a signal on the first-type signal line is different from a signal on the first positioning pin, and the first-type signal line does not overlap with the first area along the direction perpendicular to the plane of the circuit board; and/or
the circuit board further comprises a second-type signal line, wherein a signal on the second-type signal line is the same as the signal on the first positioning pin, and the second-type signal line overlaps with the first area along the direction perpendicular to the plane of the circuit board.

2. The circuit board according to claim 1, wherein the first area comprises a first sub-area located on the first surface, and the first sub-area covers the first positioning pin along the direction perpendicular to the plane of the circuit board; and
the first-type signal line comprises a first signal line located on the first surface, and the first signal line does not pass through the first sub-area.

3. The circuit board according to claim 2, wherein the first connecting seat is configured for corresponding electrical connection with a second connecting seat; and the first connecting seat comprises a first positioning portion, the first positioning pin is located on the first positioning portion, the second connecting seat comprises a second positioning portion, and the second positioning portion is arranged corresponding to the first positioning portion;
along the direction perpendicular to the plane of the circuit board, a projection of the first positioning portion onto the first surface is a first projection, and a projection of the second positioning portion onto the first surface is a second projection; and
the first sub-area protrudes beyond a larger one in area of the first projection and the second projection along a first direction, and the first direction is parallel to the plane of the circuit board.

4. The circuit board according to claim 3, wherein a distance by which the first sub-area protrudes beyond the larger one in area of the first projection and the second projection along the first direction is D, where 0.15 mm ≤ D ≤ 0.25 mm.

5. The circuit board according to claim 3, wherein the first sub-area comprises a positioning area where the first positioning portion is arranged, and an adjacent area adjacent to the positioning area, and the adjacent area at least partially surrounds the positioning area.

6. The circuit board according to claim 5, wherein no signal trace is arranged in the adjacent area.

7. The circuit board according to claim 1, wherein the first area comprises a first sub-area located on the first surface, and the first sub-area covers the first positioning pin along the direction perpendicular to the plane of the circuit board; and
the second-type signal line comprises a second signal line located on the first surface, and
at least a part of the second signal line is located in the first sub-area.

8. The circuit board according to claim 7, wherein in the first sub-area, an area of the second signal line is not less than 50% of an area of the first sub-area.

9. The circuit board according to claim 7, wherein the second signal line is electrically connected to the first positioning pin, and the second signal line covers the first positioning pin along the direction perpendicular to the plane of the circuit board.

10. The circuit board according to claim 1, wherein the first area comprises a second sub-area located on the second surface, and the second sub-area covers the first positioning pin along the direction perpendicular to the plane of the circuit board; and
the first-type signal line comprises a third signal line located on the second surface, and the third signal line does not pass through the second sub-area.

11. The circuit board according to claim 10, wherein the first connecting seat comprises a first positioning portion, and the first positioning pin is located on the first positioning portion; and
the second sub-area covers the first positioning portion along the direction perpendicular to the plane of the circuit board.

12. The circuit board according to claim 11, wherein a projection of the first positioning portion onto the second surface along the direction perpendicular to the plane of the circuit board is a third projection; and
a distance by which the second sub-area protrudes beyond the third projection along a first direction is L, where 0.15 mm ≤ L ≤ 0.25 mm, and the first direction is parallel to the plane of the circuit board.

13. The circuit board according to claim 10, wherein no signal trace is arranged in the second sub-area.

14. The circuit board according to claim 1, wherein the first area comprises a second sub-area located on the second surface, and the second sub-area covers the first positioning pin along the direction perpendicular to the plane of the circuit board; and
the second-type signal line comprises a fourth signal line located on the second surface, and
at least a part of the fourth signal line is located in the second sub-area.

15. The circuit board according to claim 14, wherein a projection of the fourth signal line onto the first surface along the direction perpendicular to the plane of the circuit board covers the first positioning pin.

16. An electronic device, comprising a circuit board, wherein the circuit board comprises a first surface and a second surface arranged opposite to each other, wherein a first connecting seat is arranged on the first surface and comprises at least one first positioning pin;
the circuit board further comprises a first area, and a projection of the first area onto the first surface along a direction perpendicular to a plane of the circuit board covers the first positioning pin;
the circuit board further comprises a first-type signal line, wherein a signal on the first-type signal line is different from a signal on the first positioning pin, and the first-type signal line does not overlap with the first area along the direction perpendicular to the plane of the circuit board; and/or
the circuit board further comprises a second-type signal line, wherein a signal on the second-type signal line is the same as the signal on the first positioning pin, and the second-type signal line overlaps with the first area along the direction perpendicular to the plane of the circuit board.
